(19) United States
(12) Patent Application Publication
(10) Pub. No.: US 2024/0213128 A1
(43) Pub. Date: Jun. 27, 2024

(54) SEMICONDUCTOR PACKAGE

(71) Applicant: Samsung Electronics Co., Ltd., Suwon-si (KR)

(72) Inventors: Jihyun LEE, Suwon-si (KR); Yongsung PARK, Suwon-si (KR)

(73) Assignee: Samsung Electronics Co., Ltd., Suwon-si, Gyeonggi-do (KR)

(21) Appl. No.: 18/529,346

(22) Filed: Dec. 5, 2023

(30) Foreign Application Priority Data
Dec. 21, 2022 (KR) 10-2022-0180911

(51) Int. Cl. H01L 23/498; H01L 23/31; H05K 1/18

(52) U.S. Cl. CPC H01L 23/49816; H01L 23/3128; H01L 23/49838; H05K 1/181; H05K 2201/10734

(57) ABSTRACT

A semiconductor package includes a wiring substrate, a solder ball on a lower surface of the wiring substrate, a ball land between the lower surface of the wiring substrate and the solder ball and having an upper surface having a circular shape, and a mask layer covering the lower surface of the wiring substrate and including an opening through which a portion of the ball land is exposed. The ball land includes a first land region which is exposed via the opening and has an upper surface having a semicircular shape with a first radius and a second land region which is integrated with a flat side surface of the first land region and has an upper surface having a semicircular shape with a second radius that is less than the first radius.

### CROSS-REFERENCE TO RELATED APPLICATION

This application is based on and claims priority under 35 U.S.C. § 119 to Korean Patent Application No. 10-2022-0180911, filed on Dec. 21, 2022, in the Korean Intellectual Property Office, the disclosure of which is incorporated by reference herein in its entirety.

### BACKGROUND

Example embodiments of inventive concepts relate to a semiconductor package, and more particularly, to a semiconductor package including a plurality of solder balls.

In some example embodiments, a semiconductor package may include a chip mounted on the upper surface of a wiring substrate, a molding layer for molding the chip, and solder balls arranged on the lower surface of the wiring substrate. The semiconductor package may be electrically connected to a board substrate using the solder balls arranged on the lower surface of the wiring substrate. Accordingly, it may be advantageous to secure mechanical and electrical reliability of the solder balls connected to the board substrate.

### SUMMARY

Inventive concepts relate to a semiconductor package with improved mechanical and electrical reliability of the solder balls.

Example embodiments of inventive concepts relate to a semiconductor package including a wiring substrate, a solder ball on a lower surface of the wiring substrate, a ball land between the lower surface of the wiring substrate and the solder ball, the ball land having an upper surface having a circular shape, and a mask layer covering the lower surface of the wiring substrate and including an opening through which a portion of the ball land is exposed. The ball land may include a first land region which is exposed via the opening and has an upper surface having a semicircular shape with a first radius and a second land region which is integrated with a flat side surface of the first land region and has an upper surface having a semicircular shape with a second radius that is less than the first radius.

According to another example embodiment of inventive concepts, there is provided a semiconductor package including a wiring substrate, a solder ball on a lower surface of the wiring substrate, a ball land between the lower surface of the wiring substrate and the solder ball, the ball land having an upper surface having a circular shape, and a mask layer covering the lower surface of the wiring substrate and including an opening through which a portion of the ball land is exposed. The ball land may include a first land region which is not covered by the mask layer and includes a first arc having a first radius, a second land region which is integrated with a flat side surface of the first land region, the second land region including a second arc having a second radius that is less than the first radius, and a third land region which is integrated with a curved side surface of the second land region, the third region including a third arc having a third radius that is greater than the first radius, and the third region being covered by the mask layer.

According to another embodiment of inventive concepts, there is provided a semiconductor package including a wiring substrate having a first surface and a second surface, a chip on the first surface of the wiring substrate and electrically connected to the wiring substrate, a solder ball on the second surface of the wiring substrate, a ball land between the second surface of the wiring substrate and the solder ball, the ball land having an upper surface having a circular shape, and a mask layer covering the second surface of the wiring substrate and including an opening through which a portion of the ball land is exposed. The ball land may include a first land region which is exposed via the opening and has an upper surface having a semicircular shape with a first radius and a second land region which is integrated with a flat side surface of the first land region and has an upper surface having a semicircular shape with a second radius that is less than the first radius. The wiring substrate may include an open region exposed via the opening, and the open region is adjacent to a curved side surface of the first land region. A distance from a center of an upper surface of the solder ball to an outermost side of the open region is about 1.3 to about 1.6 times a distance from the center of the upper surface of the solder ball to an outermost side of the first land region, and a distance from the center of the upper surface of the solder ball to an outermost side of the first land region is about 1.1 to about 1.4 times the distance from the center of the upper surface of the solder ball to the outermost side of the second land region. The solder ball is fused with the upper surface and an outer wall of the first land region, and the chip may be provided in the form of a single chip or a laminated chip.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view for describing a semiconductor package according to an example embodiment;

FIG. 2 is a partially enlarged view of the semiconductor package of FIG. 1;

FIGS. 3 and 4 are cross-sectional views for describing solder ball lands of a wiring substrate of a semiconductor package according to an example embodiment;

FIG. 5 is a cross-sectional view for describing a ball land of a semiconductor package according to another example embodiment;

FIG. 6 is a cross-sectional view for describing a ball land of a semiconductor package according to another example embodiment;

FIGS. 7 and 8 are cross-sectional views for describing a ball land of a semiconductor package according to another example embodiment;

FIG. 9 is a cross-sectional view for describing a ball land of a semiconductor package according to another example embodiment;

FIG. 10 is a cross-sectional view for describing a ball land of a semiconductor package according to another example embodiment;

FIG. 11 is an image showing bonding reliability of an external terminal in a semiconductor package according to conventional arts;

FIG. 12 is a block diagram showing a configuration of a semiconductor package according to an example embodiment; and

FIG. 13 is a block diagram schematically showing a configuration of a semiconductor package according to an example embodiment.

### DETAILED DESCRIPTION

Hereinafter, some example embodiments are described in detail with reference to the accompanying drawings. The following example embodiments of the inventive concepts may, however, be embodied in different forms and should not be constructed as limited to the example embodiments set forth herein. Rather, these example embodiments are provided so that this disclosure will be thorough and complete, and will fully convey the scope of the inventive concepts to those skilled in the art.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

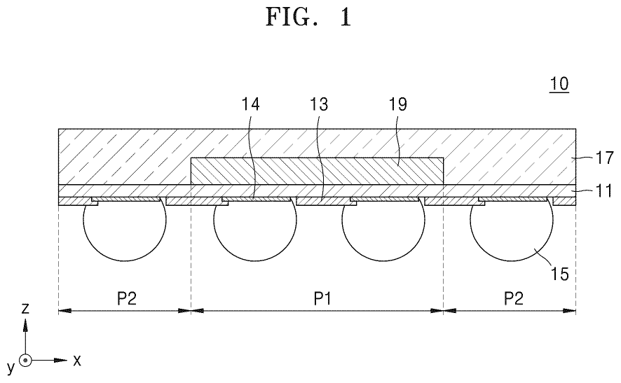

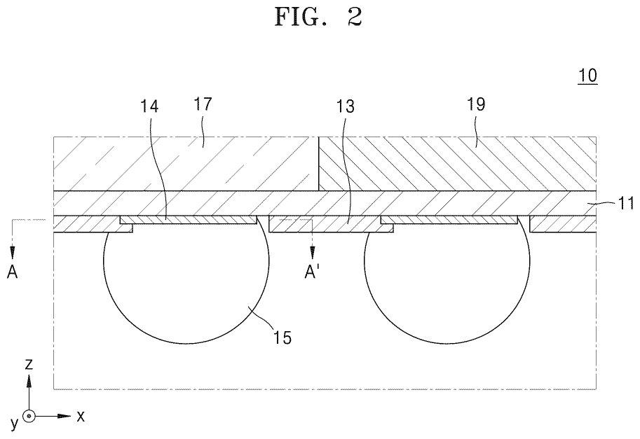

FIG. 1 is a cross-sectional view for describing a semiconductor package according to an example embodiment. FIG. 2 is a partially enlarged view of the semiconductor package of FIG. 1.

For example, the semiconductor package 10 may include a wiring substrate 11, a chip 19, a molding layer 17, and a solder ball 15. FIG. 1 is a cross-sectional view taken along a first direction (X direction) and a third direction (Z direction) with respect to a surface of the wiring substrate 11. The third direction may be perpendicular to the surface of the wiring substrate 11.

The wiring substrate 11 may include a printed circuit board (PCB). The wiring substrate 11 may include a ball land 14 and a mask layer 13 covering a portion of the ball land 14. A plurality of ball lands 14 may be provided, and the plurality of ball lands 14 may be spaced apart from each other in the first direction (X direction).

The wiring substrate 11 may include at least one of prepreg resin, thermosetting epoxy resin, thermoplastic epoxy resin, and filler-containing resin. A substrate wiring layer is formed in the wiring substrate 11 and may be electrically connected to the chip 19 and the ball land 14. The mask layer 13 may include a photo sensitive resist (PSR).

The ball land 14 may include a metal layer. The ball land 14 may include a single layer or a composite layer having metal such as tin, silver, or copper. The ball land 14 may be a mixture of a solder mask defined type (SMD type) and a non-solder mask defined type (NSMD type) arranged entirely between mask layers 13, but the example embodiment is not necessarily limited thereto.

The SMD type may be a ball land defined by the mask layer 13, and the NSMD type is a ball land not defined by the mask layer 13. As the ball land 14 is provided in the form of a mixture of SMD type and NSMD type, the semiconductor package 10 according to the example embodiment may improve bonding characteristics between the solder ball 15 and the ball land 14, thus making it possible to exhibit improved performance during a drop test. As a result, the semiconductor package 10 according to the example embodiment may improve mechanical and electrical reliability of the solder ball 15.

As illustrated in FIGS. 1 and 2, one side of the ball land 14 may be in contact with the mask layer 13, and the other side thereof may be spaced apart from the mask layer 13. A region of the ball land 14 in contact with the mask layer 13 may include the SMD type, and a region of the ball land 14 spaced apart from the mask layer 13 may include the NSMD type. The plurality of ball lands 14 may be arranged in a central region P1 or a peripheral region P2 of the wiring substrate 11. The central region P1 of the wiring substrate 11 may vertically overlap the chip 19, and the peripheral region P2 of the wiring substrate 11 may not overlap the chip 19.

In some example embodiments, the peripheral region P2 may include corner regions of the wiring substrate 11. In some example embodiments, the ball lands 14 arranged in the peripheral region P2 may include dummy solder ball lands that are not electrically connected to the chip 19.

The chip 19 may be disposed on the central region P1 of the wiring substrate 11. In some example embodiments, the chip 19 may include a single chip. The chip 19 may be electrically connected to the wiring substrate 11. The chip 19 may be connected to the wiring substrate 11 through bonding wires or bumps. The chip 19 may include individual devices. The individual devices may include various microelectronics devices, for example, metal-oxide-semiconductor field effect transistors (MOSFET), such as complementary metal-oxide-semiconductor (CMOS) transistors, system large scale integration (LSI), image sensors, such as CMOS imaging sensors (CIS), micro-electro-mechanical systems (MEMS), active elements, passive elements, etc.

In some example embodiments, the chip 19 may include a logic chip, a power management integrated circuit (PMIC) chip, or a memory chip. In some example embodiments, the logic chip may include a memory controller chip, a central processing unit (CPU) chip, a graphic processing unit (GPU) chip, or an application processor (AP) chip.

In some example embodiments, the memory chip may include a dynamic random access memory (DRAM) chip, a static random access memory (SRAM) chip, a flash memory chip, an electrically erasable and programmable read-only memory (EPROM) chip, a phase-change random access memory (PRAM) chip, a magnetic random access memory (MRAM) chip, or a resistive random access memory (RRAM) chip.

The molding layer 17 may seal the chip 19 on the wiring substrate 11. The molding layer 17 may be formed on both side surfaces and the upper surface the chip 19 to seal the chip 19. The molding layer 17 may include, for example, a silicone-based material, a thermosetting material, a thermoplastic material, or an ultraviolet (UV) treated material. The molding layer 17 may include polymer such as resin, and may include, for example, an epoxy molding compound (EMC).

The solder ball 15 may be fused to the ball land 14. The solder ball 15 may be attached to the ball land 14. The solder ball 15 may include one metal or a metal alloy comprising copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

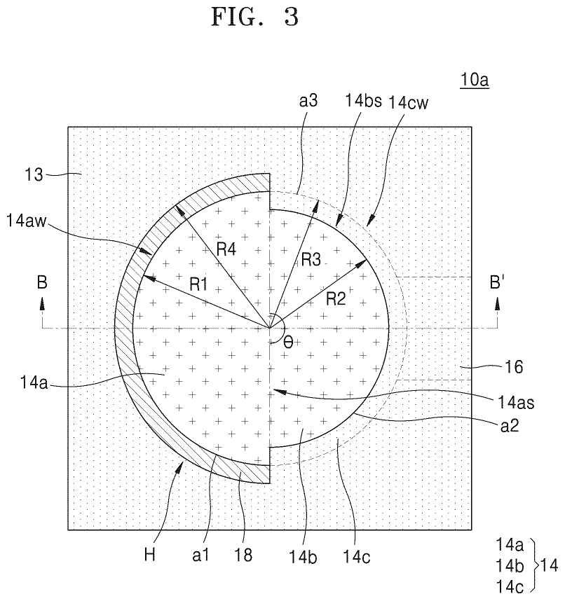

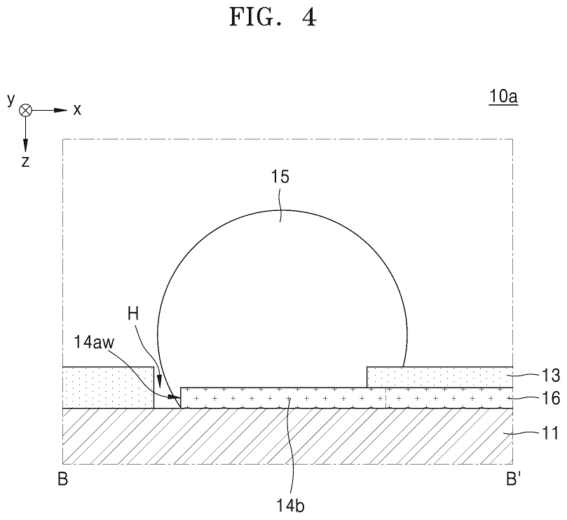

FIGS. 3 and 4 are cross-sectional views for describing solder ball lands of a wiring substrate of a semiconductor package according to an example embodiment.

A semiconductor package 10a illustrated in FIGS. 3 and 4 may be an example of the semiconductor package 10 illustrated in FIGS. 1 and 2. Referring to FIGS. 3 and 4, the mask layer 13 may cover at least a part of the lower surface of the wiring substrate 11 and include an opening H through which a portion of the ball land 14 is exposed. Here, the ball land 14 may be exposed via the opening H. However, the entire region of the ball land 14 is not exposed. Only some areas may be exposed, and other areas may be covered and buried by the mask layer 13.

According to an example embodiment, the ball land 14 may include a first land region 14a which is exposed via the opening H and has an upper surface having a semicircular shape with a first radius R1. The first land region 14a may include a first arc a1 having the first radius R1. The first land region 14a is not in contact with or covered by the mask layer 13, unlike a second land region 14b and a third land region 14c described below. A curved side wall of the first land region 14a may be exposed.

Also, according to an example embodiment, the ball land 14 may include a second land region 14b which is integrated with a flat side surface 14as of the first land region 14a of the ball land 14 and has an upper surface having a semicircular shape with a second radius that is less than the first radius R1. The second land region 14b may include a second arc a2 having a second radius R2. The second land region 14b may include a region in contact with the mask layer 13.

According to an example embodiment, the ball land 14 may further include a third land region 14c which is integrated with a curved side surface 14bs of the second land region 14b and covered by the mask layer 13. The third land region 14c may include a third arc a3 having a third radius R3. Here, a sum of an area of an upper surface of the third land region 14c and an area of the upper surface of the second land region 14b may be equal to an area of the upper surface of the first land region 14a. That is, the sum of the upper surface of the second land region 14b and the upper surface of the third land region 14c may have a semicircular shape having the first radius R1. Also, the third land region 14c may not be a separate part spaced apart from the first land region 14a, but may be integrally formed with the first land region 14a. The third land region 14c may have a hoof shape having a certain arc.

According to an example embodiment, a wiring line 16 may be provided which is connected to a curved side wall 14cw of the third land region 14c. Here, the wiring line 16 may be covered by the mask layer 13. The wiring line 16 may be connected to the curved side wall 14cw of the third land region 14c having the third radius R3. The wiring line 16 may include input/output lines of the ball land 14. The ball land 14 and the wiring line 16 may include the same conductive material, such as a copper layer and a noble metal layer, but the scope of the inventive concepts is not limited to this example embodiment. For example, the ball land 14 and the wiring line 16 may include different conductive materials.

Also, the sum of the upper surfaces of the first land region 14a, the second land region 14b, and the third land region 14c of the ball land 14 may form a single circular shape. In other words, the ball land 14 may have a single disc shape. Therefore, the SMD and NSMD regions may be distinguished from each other by adjusting whether the region is buried or not by the mask layer 13, without separately forming the SMD and NSMD regions. Therefore, the second land region 14b and the third land region 14c, which are included in the SMD region, and the first land region 14a, which is included in the NSMD region, may not be separately manufactured, and thus, more efficient manufacturing is possible.

According to an example embodiment, the wiring substrate 11 may include an open region 18 exposed via the opening H. The open region 18 may include a portion of the upper surface of the wiring substrate 11 exposed via the opening H. The open region 18 may have a hoof shape having a certain arc. The open region 18 may be exposed adjacent to the curved side wall 14aw of the first land region 14a when viewed in a vertical direction.

The sum of the upper surfaces of the first land region 14a, the second land region 14b, and the third land region 14c of the ball land 14 forms a single circular shape, and thus, the distance from the center of the upper surface of the ball land 14 to the outermost side of the third land region 14c may be equal to the distance from the center of the upper surface of the ball land 14 to the outermost side of the first land region 14a. The distance from the center of the upper surface of the ball land 14 to the outermost side of the third land region 14c may be defined as the third radius R3 of the third arc a3. In other words, this may be understood as that the third radius R3 of the third arc a3 or the distance to the outermost side of the third land region 14c of the ball land 14 may be equal to the first radius R1 of the first land region 14a.

According to an example embodiment, the distance from the center of the upper surface of the ball land 14 to the outermost side of the first land region 14a may be about 1.1 to about 1.4 times the distance from the center of the upper surface of the ball land 14 to the outermost side of the second land region 14b. The distance from the center of the upper surface of the ball land 14 to the outermost side of the first land region 14a may be defined as the first radius R1 of the first land region 14a, and the distance from the center of the upper surface of the ball land 14 to the outermost side of the second land region 14b may be defined as the second radius R2 of the second land region 14b. That is, the radius of the second land region 14b having a semicircular shape may be smaller than the radius of the first land region 14a having a semicircular shape. This is because the ball land 14 may be defined as being divided into the second land region 14b and the third land region 14c with respect to the mask layer 13.

According to an example embodiment, the distance from the center of the upper surface of the ball land 14 to the outermost side of the open region 18 may be about 1.1 to about 1.4 times the distance from the center of the upper surface of the ball land 14 to the outermost side of the first land region 14a. The distance from the center of the upper surface of the ball land 14 to the outermost side of the open region 18 may be defined as a fourth radius R4 of an arc of the open region 18. The outermost side of the first land region 14a may be defined as the outermost side of the ball land 14. The first land region 14a is not covered by the mask layer 13, and thus, the open region 18 adjacent to the curved side wall 14aw of the first land region 14a may be exposed. The open region 18 may be exposed adjacent to the curved side wall 14aw of the first land region 14a and include a fourth arc having the fourth radius R4.

The ball land 14 may have a composite structure in which the SMD and the NSMD are coupled to each other. Accordingly, the solder ball 15 may be bonded to the first land region 14a of the ball land 14 exposed from the opening H, and may be further bonded to the curved side wall 14aw of the first land region 14a. Therefore, the solder ball 15 may be bonded to the curved side wall 14aw of the first land region 14a without being directly bonded to the wiring line 16. Accordingly, the first land region 14a and the second land region 14b may be fused with the solder ball 15, and the third land region 14c may not be fused with the solder ball 15. The solder ball 15 may be fused with the upper surface of the first land region 14a and the curved side wall 14aw of the first land region 14a.

When the third arc a3 of the third land region 14c, which is in contact with the wiring line 16 and buried by the mask layer 13, is short, the possibility that cracks occur at a junction between the ball land 14 and the wiring line 16 increases. Therefore, in the example embodiment in which the third radius R3 and the third arc a3 of the third land region 14c are equal to the first radius R1 and the first arc a1 of the first land region 14a, respectively, the possibility that cracks occur at a junction between the ball land 14 and the wiring line 16 may be reduced.

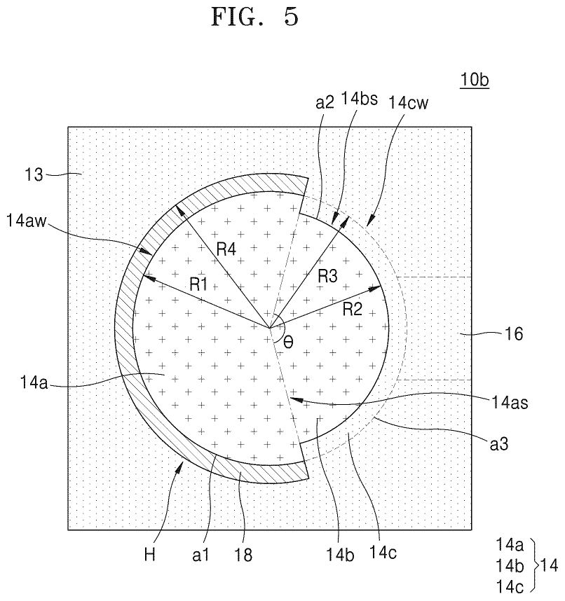

FIG. 5 is a cross-sectional view for describing a ball land of a semiconductor package according to another example embodiment. The configuration of a semiconductor package 10b illustrated in FIG. 5 is substantially similar to that of the semiconductor package 10a illustrated in FIGS. 3 and 4 except that the shapes of ball lands 14 are different from each other. Accordingly, descriptions of components identical or similar to those of the semiconductor package 10a given with reference to FIGS. 3 and 4 are omitted or simplified.

Referring to FIG. 5, a ball land 14 may include a first land region 14a which is exposed via an opening H and has an upper surface having a portion of a circular shape with a first radius R1. The first land region 14a may include a first arc a1 having the first radius R1. The first land region 14a is not in contact with or covered by a mask layer 13, unlike a second land region 14b and a third land region 14c described below. A curved side wall of the first land region 14a may be exposed.

Also, according to an example embodiment, the ball land 14 may include a second land region 14b which is integrated with a flat side surface 14as of the first land region 14a of the ball land 14 and has an upper surface having a fan shape with a second radius that is less than the first radius R1. The second land region 14b may include a second arc a2 having a second radius R2. The second land region 14b may include a region in contact with the mask layer 13.

According to an example embodiment, the ball land 14 may further include a third land region 14c which is integrated with a curved side surface 14bs of the second land region 14b and covered by the mask layer 13. The third land region 14c may include a third arc a3 having a third radius R3. Here, a sum of an area of an upper surface of the third land region 14c and an area of the upper surface of the second land region 14b may be less than an area of the upper surface of the first land region 14a. The third land region 14c may not be a separate part spaced apart from the first land region 14a, but may be integrally formed with the first land region 14a. The third land region 14c may have a hoof shape having a certain arc.

The ball land 14 may have a composite structure in which the SMD and the NSMD are combined coupled to each other. Accordingly, the solder ball 15 may be bonded to the first land region 14a of the ball land 14 exposed from the opening H, and may be further bonded to the curved side wall 14aw of the first land region 14a. Therefore, the solder ball 15 may be bonded to the curved side wall 14aw of the first land region 14a without being directly bonded to a wiring line 16. The first land region 14a and the second land region 14b may be fused with the solder ball 15, and the third land region 14c may not be fused with the solder ball 15. The solder ball 15 may be fused with the upper surface of the first land region 14a and the curved side wall 14aw of the first land region 14a.

An angle θ of the third land region 14c having the fan shape may be greater than about 90 degrees and less than about 180 degrees. When the third arc a3 of the third land region 14c, which is in contact with the wiring line 16 and buried by the mask layer 13, is short, the possibility that cracks occur at a junction between the ball land 14 and the wiring line 16 may increase. When the third arc a3 of the third land region 14c is substantially equal to the length of the contact portion between the wiring line 16 and the ball land 14, the probability that cracks occur at the junction of the wiring line 16 may increase. Therefore, in the example embodiment in which the third arc a3 of the third land region 14c is maintained over a certain length, the possibility that cracks occur at a junction between the ball land 14 and the wiring line 16 may be reduced.

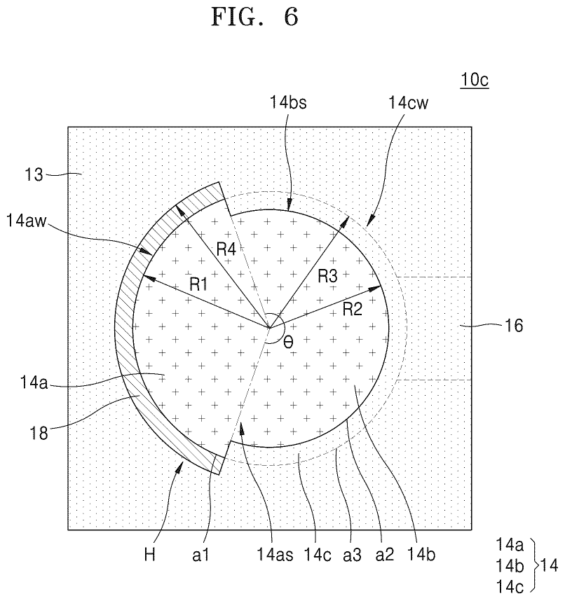

FIG. 6 is a cross-sectional view for describing a ball land of a semiconductor package according to another example embodiment. The configuration of a semiconductor package 10c illustrated in FIG. 6 is substantially similar to that of the semiconductor package 10a illustrated in FIGS. 3 and 4 except that the shapes of ball lands 14 are different from each other. Accordingly, descriptions of components identical or similar to those of the semiconductor package 10a given with reference to FIGS. 3 and 4 are omitted or simplified.

Referring to FIG. 6, a ball land 14 may include a first land region 14a which is exposed via an opening H and has an upper surface having a fan shape with a first radius R1. The first land region 14a may include a first arc a1 having the first radius R1. The first land region 14a is not in contact with or covered by a mask layer 13, unlike a second land region 14b and a third land region 14c described below. A curved side wall of the first land region 14a may be exposed.

Also, according to an example embodiment, the ball land 14 may include a second land region 14b which is integrated with a flat side surface 14as of the first land region 14a of the ball land 14 and has an upper surface having a portion of a circular shape with a second radius that is less than the first radius R1. The second land region 14b may include a second arc a2 having a second radius R2. The second land region 14b may include a region in contact with the mask layer 13.

According to an example embodiment, the ball land 14 may further include a third land region 14c which is integrated with a curved side surface 14bs of the second land region 14b and covered by the mask layer 13. The third land region 14c may include a third arc a3 having a third radius R3. Here, a sum of an area of an upper surface of the third land region 14c and an area of the upper surface of the second land region 14b may be greater than to an area of the upper surface of the first land region 14a. The third land region 14c may not be a separate part spaced apart from the first land region 14a, but may be integrally formed with the first land region 14a. The third land region 14c may have a hoof shape having a certain arc.

The ball land 14 may have a composite structure in which the SMD and the NSMD are coupled to each other. Accordingly, the solder ball 15 may be bonded to the first land region 14a of the ball land 14 exposed from the opening H, and may be further bonded to the curved side wall 14aw of the first land region 14a. Therefore, the solder ball 15 may be bonded to the curved side wall 14aw of the first land region 14a without being directly bonded to a wiring line 16. The first land region 14a and the second land region 14b may be fused with the solder ball 15, and the third land region 14c may not be fused with the solder ball 15. The solder ball 15 may be fused with the upper surface of the first land region 14a and the curved side wall 14aw of the first land region 14a.

An angle θ of the third land region 14c having the fan shape may be greater than about 180 degrees and less than about 270 degrees. When the third arc a3 of the third land region 14c, which is in contact with the wiring line 16 and buried by the mask layer 13, is short, the possibility that cracks occur at a junction between the ball land 14 and the wiring line 16 may increase. When the third arc a3 of the third land region 14c is substantially equal to the length of the contact portion between the wiring line 16 and the ball land 14, the probability that cracks occur at the junction of the wiring line 16 may increase. Therefore, in the example embodiment in which the third arc a3 of the third land region 14c is longer than a semicircular arc having the third radius R3, the possibility that cracks occur at a junction between the ball land 14 and the wiring line 16 may be reduced.

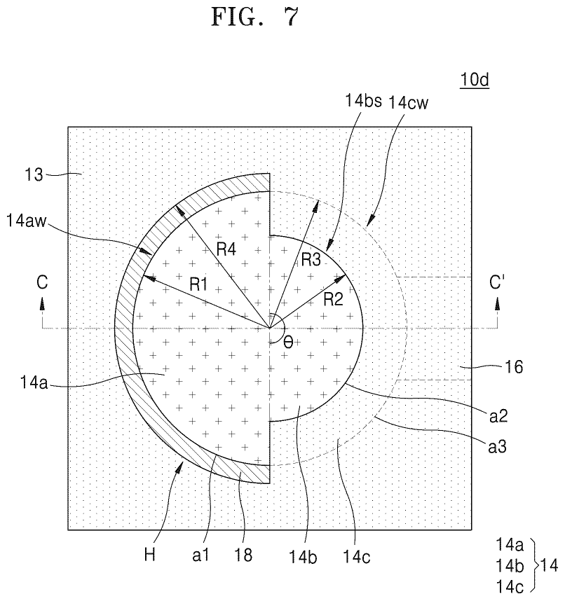

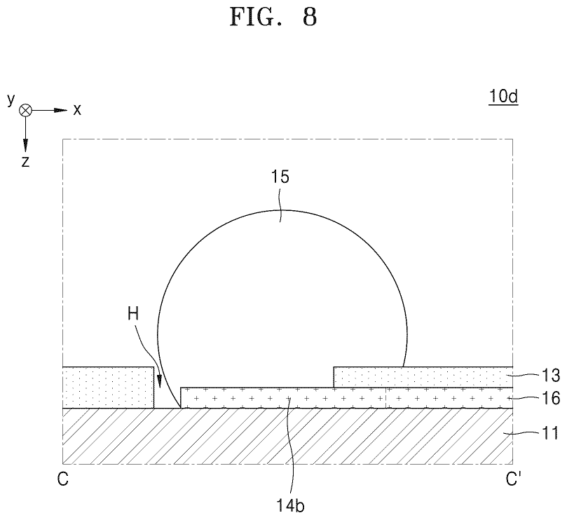

FIGS. 7 and 8 are cross-sectional views for describing a ball land of a semiconductor package according to another example embodiment. The configuration of a semiconductor package 10d illustrated in FIGS. 7 and 8 is substantially the same as or similar to that of the semiconductor package 10a illustrated in FIGS. 3 and 4 except that a second radius R2 of a second land region 14b of the semiconductor package 10d is smaller than that of the semiconductor package 10a. Accordingly, descriptions of components identical or similar to those of the semiconductor package 10a given with reference to FIGS. 3 and 4 are omitted or simplified.

According to an example embodiment, a first radius R1 of a first land region 14a of a ball land 14 may be about 1.4 times to about 1.7 times a second radius R2 of a second land region 14b. However, as in the semiconductor package 10a illustrated in FIGS. 3 and 4, a third radius R3 of a third land region 14c may be about 1.1 to about 1.4 times that of the first land region 14a.

When the width of the third land region 14c, which is in contact with a wiring line 16 and buried by a mask layer 13, is short, the possibility that cracks occur at a junction between the ball land 14 and the wiring line 16 may increase. Therefore, in the example embodiment in which the width of the third land region 14c is increased by reducing the second radius R2 of the second land region 14b, the possibility that cracks occur at a junction between the ball land 14 and the wiring line 16 may be reduced.

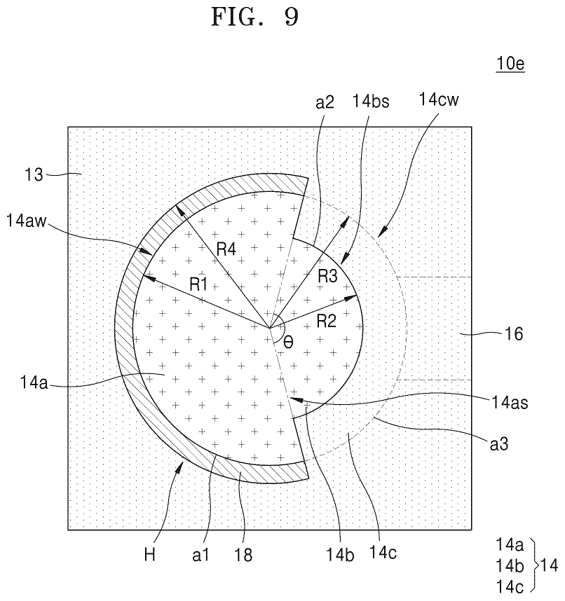

FIG. 9 is a cross-sectional view for describing a ball land of a semiconductor package according to another example embodiment. The configuration of a semiconductor package 10e illustrated in FIG. 9 is substantially the same as or similar to that of the semiconductor package 10b illustrated in FIG. 5 except that a second radius R2 of a second land region 14b of the semiconductor package 10e is smaller than that of the semiconductor package 10b. Accordingly, descriptions of components identical or similar to those of the semiconductor package 10b given with reference to FIG. 5 are omitted or simplified.

According to an example embodiment, a first radius R1 of a first land region 14a of a ball land 14 may be about 1.4 times to about 1.7 times a second radius R2 of a second land region 14b. However, as in the semiconductor package 10b illustrated in FIG. 5, a third radius R3 of a third land region 14c may be about 1.1 to about 1.4 times that of the first land region 14a.

When the width of the third land region 14c, which is in contact with a wiring line 16 and buried by a mask layer 13, is short, the possibility that cracks occur at a junction between the ball land 14 and the wiring line 16 may increase. Therefore, in the example embodiment in which the width of the third land region 14c is increased by reducing the second radius R2 of the second land region 14b, the possibility that cracks occur at a junction between the ball land 14 and the wiring line 16 may be reduced.

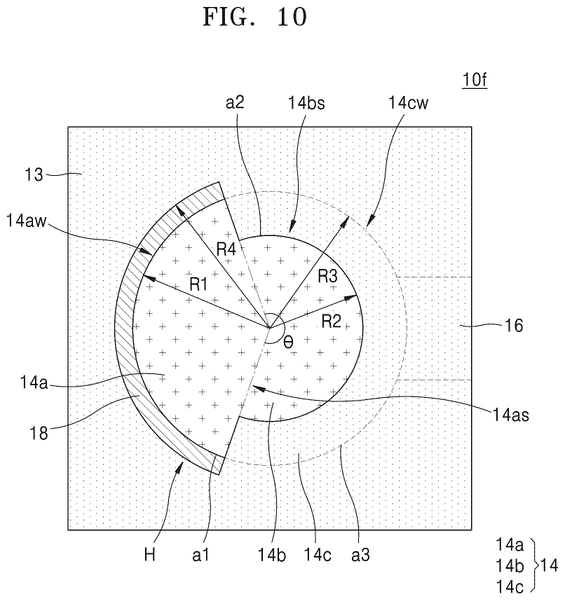

FIG. 10 is a cross-sectional view for describing a ball land of a semiconductor package according to another example embodiment. The configuration of a semiconductor package 10f illustrated in FIG. 10 is substantially the same as or similar to that of the semiconductor package 10c illustrated in FIG. 6 except that a second radius R2 of a second land region 14b of the semiconductor package 10f is smaller than that of the semiconductor package 10c. Accordingly, descriptions of components identical or similar to those of the semiconductor package 10c given with reference to FIG. 6 are omitted or simplified.

According to an example embodiment, a first radius R1 of a first land region 14a of a ball land 14 may be about 1.4 times to about 1.7 times a second radius R2 of a second land region 14b. However, as in the semiconductor package 10c illustrated in FIG. 6, a third radius R3 of a third land region 14c may be about 1.1 to about 1.4 times that of the first land region 14a.

When the width of the third land region 14c, which is in contact with a wiring line 16 and buried by a mask layer 13, is short, the possibility that cracks occur at a junction between the ball land 14 and the wiring line 16 may increase. Therefore, in the example embodiment in which the width of the third land region 14c is increased by reducing the second radius R2 of the second land region 14b, the possibility that cracks occur at a junction between the ball land 14 and the wiring line 16 may be reduced.

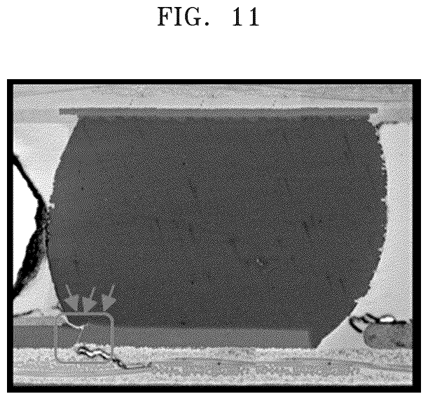

FIG. 11 is an image showing bonding reliability of an external terminal in a semiconductor package according to conventional arts. Referring to FIG. 11, cracks may occur in a wiring line in the NSMD type. These cracks may occur at interfaces of external terminals that cover ball lands. Furthermore, in the NSMD type, the bonding area of the external terminals is widened so that the density of the external terminals is reduced, and it is difficult to densely arrange wiring lines. Accordingly, it is necessary to properly balance the advantages and disadvantages of the SMD type or the NSMD type.

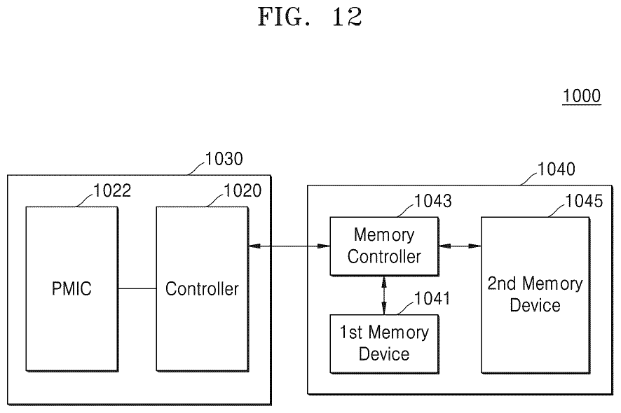

FIG. 12 is a block diagram showing a configuration of a semiconductor package according to an example embodiment.

For example, a semiconductor package 1000 may correspond to any one of the semiconductor packages 10a to 10f according to the example embodiment. The semiconductor package 1000 may include a controller chip 1020, a first memory chip 1041, a second memory chip 1045, and a memory controller 1043. The semiconductor package 1000 may further include a power management integrated circuit (PMIC) 1022 for supplying current of an operating voltage to each of the controller chip 1020, the first memory chip 1041, the second memory chip 1045, and the memory controller 1043. The operating voltages applied to the respective components may be equally or differently designed.

A lower package 1030 including the controller chip 1020 and the PMIC 1022 may include any one of the above-described semiconductor packages 10a to 10f according to the example embodiment. An upper package 1040 including the first memory chip 1041, the second memory chip 1045, and the memory controller 1043 may include any one of the above-described semiconductor packages 10a to 10f according to the example embodiment.

The semiconductor package 1000 may be formed to be included in a personal computer (PC) or a mobile device. The mobile device may be formed as a laptop computer, a mobile phone, a smart phone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile internet device (MID), a wearable computer, an internet of things (IoT) device, an internet of everything (IoE) device, or a drone.

The controller chip 1020 may control an operation of each of the first memory chip 1041, the second memory chip 1045, and the memory controller 1043. For example, the controller chip 1020 may be formed as an integrated circuit (IC), a system on chip (SoC), an application processor (AP), a mobile AP, a chip set, or a set of chips. The controller chip 1020 may include a central processing unit (CPU), a graphics processing unit (GPU), and/or a modem. In some example embodiments, the controller chip 1020 may perform a function of the modem and a function of the AP.

The memory controller 1043 may control the second memory chip 1045 according to control of the controller chip 1020. The first memory chip 1041 may be formed as a volatile memory device. The volatile memory device may be formed as a random access memory (RAM), a dynamic RAM (DRAM), or a static RAM (SRAM), but the example embodiment is not limited thereto. The second memory chip 1045 may be formed as a storage memory device. The storage memory device may be formed as a nonvolatile memory device.

The storage memory device may be formed as a flash-based memory device, but the example embodiment is not limited thereto. The second memory chip 1045 may be formed as a NAND-type flash memory device. The NAND-type flash memory device may include a 2-dimensional memory cell array or 3-dimensional memory cell array. The 2-dimensional memory cell array or the 3-dimensional memory cell array may include a plurality of memory cells, and each of the plurality of memory cells may store 1-bit information or 2-bit or more information.

When the second memory chip 1045 is formed as the flash-based memory device, the memory controller 1043 may use (or support) a multimedia card (MMC) interface, an embedded MMC (eMMC) interface, or a universal flash storage (UFS) interface, but the example embodiment is not limited thereto.

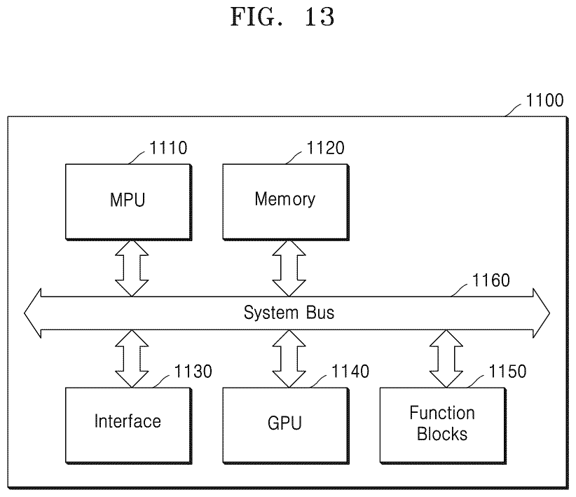

FIG. 13 is a block diagram schematically showing a configuration of a semiconductor package according to an example embodiment.

For example, a semiconductor package 1100 may include a micro processing unit (MPU) 1110, memory 1120, an interface 1130, a graphics processing unit (GPU) 1140, function blocks 1150, and a bus 1160 for connecting same. The semiconductor package 1100 may include both the MPU 1110 and the GPU 1140 but may include only one thereof.

The MPU 1110 may include a core and an L2 cache. For example, the MPU 1110 may include multi-cores. Each core of the multi-cores may have the same or different functions. Also, each core of the multi-cores may be simultaneously activated, or activation times of the multi-cores may be different from each other. The memory 1120 may store the results of processing on the function blocks 1150 according to control of the MPU 1110. For example, as contents stored in the L2 cache of the MPU 1110 are flushed, the contents may be stored in the memory 1120. The interface 1130 may establish an interface with external devices. For example, the interface 1130 may establish an interface with a camera, a liquid crystal display (LCD), and a speaker.

The GPU 1140 may perform graphics functions. For example, the GPU 1140 may perform video codec or may process 3D graphics. The function blocks 1150 may perform various functions. For example, when the semiconductor package 1100 includes an AP used in the mobile device, part of the function blocks 1150 may perform a communication function.

The semiconductor package 1100 may include any one of the semiconductor packages 10a to 10f described above in the example embodiment. The MPU 1110 and/or the GPU 1140 may include any one of the semiconductor packages 10a to 10f described above. The memory 1120 may include any one of the semiconductor packages 10a to 10f described above. The interface 1130 and the function blocks 1150 may include any one of the semiconductor packages 10a to 10f described above.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments of inventive concepts have been shown and described with reference to the presented example embodiments, it will be understood that various changes in form and details may be made therein without departing from the spirit and scope of the following claims.

What is claimed is:

1. A semiconductor package comprising:
a wiring substrate;
a solder ball on a lower surface of the wiring substrate;
a ball land between the lower surface of the wiring substrate and the solder ball, the ball land having an upper surface having a circular shape; and
a mask layer covering the lower surface of the wiring substrate and including an opening configured to expose a portion of the ball land,
the ball land including,
a first land region exposed via the opening, the first land region including an upper surface having a semicircular shape with a first radius; and
a second land region integrated with a flat side surface of the first land region, the second land region including an upper surface having a semicircular shape with a second radius that is less than the first radius.

2. The semiconductor package of claim 1, wherein
the ball land further includes a third land region integrated with a curved side surface of the second land region and covered by the mask layer, and
a sum of an area of an upper surface of the third land region and an area of the upper surface of the second land region is equal to an area of the upper surface of the first land region.

3. The semiconductor package of claim 2, further comprising:
a wiring line connected to a curved side wall of the third land region, the wiring line being covered by the mask layer.

4. The semiconductor package of claim 2, wherein a distance from a center of an upper surface of the ball land to an outermost side of the third land region is equal to a distance from the center of the upper surface of the ball land to an outermost side of the first land region.

5. The semiconductor package of claim 2, wherein
the first land region and the second land region are fused with the solder ball, and
the third land region is not fused with the solder ball.

6. The semiconductor package of claim 1, wherein
the wiring substrate includes an open region exposed via the opening, and
the open region is adjacent to a curved side surface of the first land region.

7. The semiconductor package of claim 6, wherein a distance from a center of an upper surface of the solder ball to an outermost side of the open region is about 1.3 to about 1.6 times a distance from the center of the upper surface of the solder ball to an outermost side of the first land region.

8. The semiconductor package of claim 1, wherein a distance from a center of an upper surface of the solder ball to an outermost side of the first land region is about 1.1 to about 1.4 times a distance from the center of the upper surface of the solder ball to an outermost side of the second land region.

9. The semiconductor package of claim 1, wherein the solder ball is fused with the upper surface and an outer wall of the first land region.

10. The semiconductor package of claim 1, further comprising:
a chip on the wiring substrate, the chip being in a form of a single chip or a laminated chip.

11. A semiconductor package comprising:
a wiring substrate;
a solder ball on a lower surface of the wiring substrate;
a ball land between the lower surface of the wiring substrate and the solder ball, the ball land having an upper surface having a circular shape; and
a mask layer covering the lower surface of the wiring substrate, the mask layer including an opening configured to expose a portion of the ball land,
the ball land including,
a first land region not covered by the mask layer, the first land region including a first arc having a first radius;
a second land region integrated with a flat side surface of the first land region, the second land region including a second arc having a second radius that is less than the first radius; and
a third land region integrated with a curved side surface of the second land region, the third land region including a third arc having a third radius that is greater than the first radius, and the third land region being covered by the mask layer.

12. The semiconductor package of claim 11, wherein
the first land region and the second land region are fused with the solder ball, and
the third land region is not fused with the solder ball.

13. The semiconductor package of claim 11, wherein
an upper surface of the first land region has a semicircular shape with the first radius,
an upper surface of the second land region has a semicircular shape with the second radius, and
a sum of an area of the upper surface of the second land region and an area of an upper surface of the third land region is equal to an area of the upper surface of the first land region.

14. The semiconductor package of claim 11, wherein
an upper surface of the second land region has a fan shape with the second radius, and
a sum of an area of the upper surface of the second land region and an area of an upper surface of the third land region is less than an area of an upper surface of the first land region.

15. The semiconductor package of claim 11, wherein
an upper surface of the first land region has a fan shape with the first radius, and
a sum of an area of an upper surface of the second land region and an area of an upper surface of the third land region is greater than an area of the upper surface of the first land region.

16. The semiconductor package of claim 11, wherein
the mask layer includes an opening configured to expose a portion of the ball land and a portion of the wiring substrate,
the wiring substrate includes an open region exposed via the opening, and
the open region is adjacent to a curved side surface of the first land region, the open region including a fourth arc having a fourth radius.

17. The semiconductor package of claim 16, wherein
a distance from a center of an upper surface of the solder ball to an outermost side of the open region is about 1.3 to about 1.6 times the distance from the center of the upper surface of the solder ball to an outermost side of the first land region, and
a distance from the center of the upper surface of the solder ball to an outermost side of the first land region is about 1.1 to about 1.4 times a distance from the center of the upper surface of the solder ball to the outermost side of the second land region.

18. The semiconductor package of claim 11, further comprising:
a wiring line connected to a curved side wall of the third land region, the wiring line being covered by the mask layer.

19. A semiconductor package comprising:
a wiring substrate having a first surface and a second surface;
a chip on the first surface of the wiring substrate and electrically connected to the wiring substrate;
a solder ball on the second surface of the wiring substrate;
a ball land between the second surface of the wiring substrate and the solder ball, the ball land having an upper surface having a circular shape; and
a mask layer covering the second surface of the wiring substrate and including an opening configured to expose a portion of the ball land,
the ball land including,
a first land region exposed via the opening, the first land region including an upper surface having a semicircular shape with a first radius; and
a second land region integrated with a flat side surface of the first land region, the second land region including an upper surface having a semicircular shape with a second radius that is less than the first radius, wherein
the wiring substrate comprises an open region exposed via the opening,
the open region is located adjacent to a curved side surface of the first land region,
a distance from a center of an upper surface of the solder ball to an outermost side of the open region is about 1.3 to about 1.6 times a distance from the center of the upper surface of the solder ball to an outermost side of the first land region,
a distance from the center of the upper surface of the solder ball to an outermost side of the first land region is about 1.1 to about 1.4 times the distance from the center of the upper surface of the solder ball to the outermost side of the second land region,
the solder ball is fused with the upper surface and an outer wall of the first land region, and
the chip being in a form of a single chip or a laminated chip.

20. The semiconductor package of claim 19, wherein
the ball land further includes a third land region integrated with a curved side surface of the second land region and covered by the mask layer,
a sum of an area of an upper surface of the third land region and an area of the upper surface of the second land region is equal to an area of the upper surface of the first land region,
a distance from the center of the upper surface of the solder ball to an outermost side of the third land region is equal to the distance from the center of the upper surface of the solder ball to the outermost side of the first land region, and
the first land region and the second land region are fused with the solder ball, and the third land region is not fused with the solder ball.
